(19) United States
(12) Patent Application Publication
(10) Pub. No.: US 2024/0152674 A1
(43) Pub. Date: May 9, 2024

(54) QUICK SIMULATION METHOD AND APPARATUS FOR INTEGRATED CIRCUIT, AND STORAGE MEDIUM

(71) Applicant: BATELAB CO., LTD., Suzhou (CN)

(72) Inventor: Zhen Li, Suzhou (CN)

(21) Appl. No.: 18/282,024

(22) PCT Filed: Aug. 5, 2022
(86) PCT No.: PCT/CN2022/110643

§ 371 Date: Sep. 14, 2023

(30) Foreign Application Priority Data
Aug. 18, 2021 (CN) 202110945784.5

(51) Int. Cl. G06F 30/30

(52) U.S. Cl. CPC G06F 30/30

(57) ABSTRACT

A quick simulation method and apparatus for an integrated circuit, and a storage medium, are provided, wherein, by dividing a large-scale integrated circuit into a plurality of sub-circuit, then performing simulation on each sub-circuit, generating a corresponding function correspondence relation formula for each of those sub-circuits for which a simulated waveform is a periodic waveform, and then, when performing simulation on the large-scale integrated circuit, directly performing simulation on each of those sub-circuits for which the waveform is not a periodic waveform, and performing calculation by using the function correspondence relation formula corresponding to each of those sub-circuits for which the simulated waveform is a periodic waveform to complete a corresponding simulation thereof, so as to realize a simulation for the whole large-scale integrated circuit. Wherein, because an output waveform obtained according to the function correspondence relation formula is the same as the simulated waveform obtained by directly performing simulation, there is no need to perform complicated matrix calculations on the circuit, thereby improving the simulation speed when the integrated circuit is subject to transient analysis.

### CROSS REFERENCE TO RELATED APPLICATIONS

The present application claims priority to Chinese patent application No. 202110462452.1, filed with the China National Intellectual Property Administration on Aug. 18, 2021 and entitled “A simulation optimization method and apparatus for transient analysis of a large-scale integrated circuit”, which is incorporated herein by reference in its entirety.

### TECHNICAL FIELD

The present application relates to the technical field of circuit simulation, particularly relates to a quick simulation method and apparatus for an integrated circuit, and a storage medium.

### BACKGROUND

When using Electronic Design Automation (EDA) simulation software to perform simulation on a circuit, the circuit is usually matriculated, and then the obtained matrix is calculated in EDA simulation software, finally, the result of matrix calculation is taken as a simulation result of the circuit. But when performing simulation on a more complicated circuit, an amount of data of the obtained matrix is relatively large after the complicated circuit is matriculated, so a calculation speed is very slow when using EDA simulation software to perform simulation based on the obtained matrix, which leads to very slow simulation speed for the circuit.

In addition, when performing simulation on the circuit, if an output signal of the circuit is a changing signal, an amount of calculation for the EDA software is very large, which is also a reason for the relatively slow simulation speed. Specifically, taking a situation that the output signal is a periodic square wave signal as an example, the simulation speed is faster when the signal is at a high level or a low level of the square wave, but the simulation speed is slower when the signal is at a transition stage between a high level and a low level, and, in the prior art, output signals of a majority of circuits are periodic signals, so the simulation speed for the corresponding circuits is relatively slow. In conclusion, how to improve the simulation speed for circuits is an urgent technical problem to be solved for technicians in this field.

### SUMMARY

An objective of the present application is to provide a quick simulation method and apparatus for an integrated circuit, and a storage medium, that do not need to perform complicated matrix calculations on the circuit, thereby improving the simulation speed when the integrated circuit is subject to transient analysis.

In order to solve above-mentioned technical problem, the present application provides a quick simulation method for an integrated circuit, comprising:
dividing a large-scale integrated circuit into a plurality of sub-circuits, and performing simulation on each sub-circuit;
when a simulated waveform of a sub-circuit is the same as an expected waveform, judging whether the simulated waveform of the sub-circuit is a periodic waveform;
if it is judged that the simulated waveform of the sub-circuit is a periodic waveform, then generating a corresponding function correspondence relation formula based on the sub-circuit; wherein, based on identical parameters of the sub-circuit as input, the simulated waveform obtained by performing simulation on the sub-circuit is the same as an output waveform calculated from the corresponding function correspondence relation formula;
based on parameters of the large-scale integrated circuit as input, directly performing simulation on each of those sub-circuits for which the simulated waveform is not a periodic waveform, and performing calculation by using the function correspondence relation formula corresponding to each of those sub-circuits for which the simulated waveform is a periodic waveform, so as to realize a simulation of the large-scale integrated circuit.

Optionally, the step of generating a corresponding function correspondence relation formula based on the sub-circuit comprises:
acquiring N groups of input parameters of the sub-circuit, wherein N is an integer greater than 2;
performing simulation on the sub-circuit based on each group of input parameters among the N groups of input parameters respectively, to obtain N simulated waveforms;
sampling the N simulated waveforms respectively, to obtain N waveform parameters;
obtaining the function correspondence relation formula based on the N groups of input parameters and the N waveform parameters.

Optionally, wherein the step of obtaining the function correspondence relation formula based on the N groups of input parameters and the N waveform parameters comprises:

taking the input parameters as independent variables and the waveform parameters as dependent variables, carrying out linear regression calculation to obtain a linear regression expression formula corresponding to the sub-circuit, and taking the obtained linear regression expression formula as the function correspondence relation formula.

Optionally, after the step of taking the input parameters as independent variables and the waveform parameters as dependent variables, carrying out linear regression calculation to obtain a linear regression expression formula corresponding to the sub-circuit, the method further comprises:
judging whether the linear regression expression formula has over-fitting or under-fitting;
if the linear regression expression formula has over-fitting or under-fitting, then taking the input parameters as independent variables and the waveform parameters as dependent variables, carrying out nonlinear regression calculation to obtain a nonlinear regression expression formula corresponding to the sub-circuit, and taking the obtained nonlinear regression expression formula as the function correspondence relation formula;
wherein the step of performing calculation by using the function correspondence relation formula corresponding to each of those sub-circuits for which the simulated waveform is a periodic waveform comprises:
performing calculation by using the linear regression expression formula or the nonlinear regression expression formula corresponding to each of those sub-circuits for which the simulated waveform is a periodic waveform.

Optionally, the step of acquiring N groups of input parameters of the sub-circuit comprises:
acquiring an upper limit value and a lower limit value of input parameters of the sub-circuit;
acquiring N−2 values between the upper limit value and the lower limit value to obtain N−2 groups of input parameters;
taking the N−2 groups of input parameters, the upper limit value, and the lower limit value together as acquired N groups of input parameters.

Optionally, after the step of sampling the N simulated waveforms respectively, to obtain N waveform parameters, the method further comprises:
calculating an i^{th} rate of change, which equals (an (i+1)^{th} waveform parameter minus an i^{th} waveform parameter)/(an (i+1)^{th} input parameter minus an i^{th} input parameter), wherein i is an integer that is less than N and not less than 1;
judging whether a difference between an (i+1)^{th} rate of change and the i^{th} rate of change is greater than a difference threshold value;
if the difference between the (i+1)^{th} rate of change and the i^{th} rate of change is greater than the difference threshold value, then recording an i^{th} interval of input parameters corresponding to the i^{th} rate of change and an (i+1)^{th} interval of input parameters corresponding to the (i+1)^{th} rate of change accordingly;
further acquiring values from the i^{th} interval of input parameters and from the (i+1)^{th} interval of input parameters to obtain M groups of input parameters;
wherein the step of performing simulation on the sub-circuit based on each group of input parameters among the N groups of input parameters respectively, to obtain N simulated waveforms, comprises:
performing simulation on the sub-circuit based on each group of input parameters among the M+N groups of input parameters respectively, to obtain M+N simulated waveforms;
wherein the step of sampling the N simulated waveforms respectively, to obtain N waveform parameters, comprises:
sampling the M+N simulated waveforms respectively, to obtain M+N waveform parameters;
wherein the step of obtaining the function correspondence relation formula based on the N groups of input parameters and the N waveform parameters comprises:
obtaining the function correspondence relation formula based on the M+N groups of input parameters and the M+N waveform parameters.

Optionally, when further acquiring values from the i^{th} interval of input parameters and from the (i+1)^{th} interval of input parameters, an amount of further acquired values is positively correlated with the difference between the (i+1)^{th} rate of change and the i^{th} rate of change.

Optionally, the step of calculating the i^{th} rate of change comprises:
constructing a coordinate system with the input parameters corresponding to a horizontal axis and the waveform parameters corresponding to a vertical axis;
in the coordinate system, marking out N coordinate points that have a one-to-one correspondence to the N groups of input parameters and the N waveform parameters;
connecting every two neighboring points of the N coordinate points sequentially with line segments;
calculating a slope of a line segment connecting an (i+1)^{th} coordinate point and an i^{th} coordinate point as the i^{th} rate of change.

Optionally, when the simulated waveform is a periodic square wave or a periodic triangular wave, the waveform parameters comprise an amplitude, a cyclic period and a duty cycle of the square wave or the triangular wave; when the simulated waveform is a sine wave, the waveform parameters comprise an amplitude, a cyclic period and an initial phase angle of the sine wave.

In order to solve above-mentioned technical problem, the present application further provides a quick simulation apparatus for an integrated circuit, comprising:
a memory, configured to store a computer program;
a processor, configured to perform the above-mentioned quick simulation method for an integrated circuit when the computer program is executed by the processor.

In order to solve above-mentioned technical problem, the present application further provides a non-transitory computer storage medium having computer-executable instructions stored thereon, and the computer-executable instructions, when executed by an electronic device, cause the electronic device to perform the above-mentioned quick simulation method for an integrated circuit.

The present application provides a quick simulation method and apparatus for an integrated circuit, and a storage medium, wherein, by dividing the large-scale integrated circuit into a plurality of sub-circuits, then performing simulation on each sub-circuit, generating a corresponding function correspondence relation formula for each of those sub-circuits for which a simulated waveform is a periodic waveform, and then, when performing simulation on the large-scale integrated circuit, directly performing simulation on each of those sub-circuits for which the simulated waveform is not a periodic waveform, and performing calculation by using the function correspondence relation formula corresponding to each of those sub-circuits for which the simulated waveform is a periodic waveform to complete a corresponding simulation thereof, so as to realize a simulation for the whole large-scale integrated circuit. Wherein, because an output waveform obtained according to the function correspondence relation formula is the same as the simulated waveform obtained by directly performing simulation, there is no need to perform complicated matrix calculations on the circuit, thereby improving the simulation speed when the integrated circuit is subject to transient analysis.

### BRIEF DESCRIPTION OF DRAWINGS

In order to more clearly illustrate the technical solution in embodiments of the present application, the drawings needed for describing the prior art and the embodiments are briefly introduced below. Apparently, the drawings described below represent only part of the embodiments of the present application, and other drawings may be obtained from these drawings without expenditure of creative efforts for a person with ordinary skill in the art.

FIG. 1 is a flow chart of a quick simulation method for an integrated circuit provided by an embodiment of the present application;

FIG. 2 is a schematic diagram of a correspondence relation between an input parameter and an amplitude parameter as provided by an embodiment of the present application;

FIG. 3 is a structural block diagram of a quick simulation apparatus for an integrated circuit provided by an embodiment of the present application;

FIG. 4 is a hardware structural diagram of an electronic device provided by an embodiment of the present application;

### DETAILED DESCRIPTION

A core concept of the present application is to provide a quick simulation method and apparatus for an integrated circuit, and a storage medium, that do not need to perform complicated matrix calculations on the circuit, thereby improving the simulation speed when the integrated circuit is subject to transient analysis.

In order to make the purpose, technical solution, and advantages of the embodiments of the present application clearer, the technical solution of the embodiments of the present application is clearly and completely described in conjunction with drawings in the embodiments of the present application, and apparently, the described embodiments represent only part of the embodiments of the present application, not all of them. Based on the embodiments described in the present application, all other embodiments obtainable by a person with ordinary skill in the art without expenditure of creative efforts fall within the scope of protection of the present application.

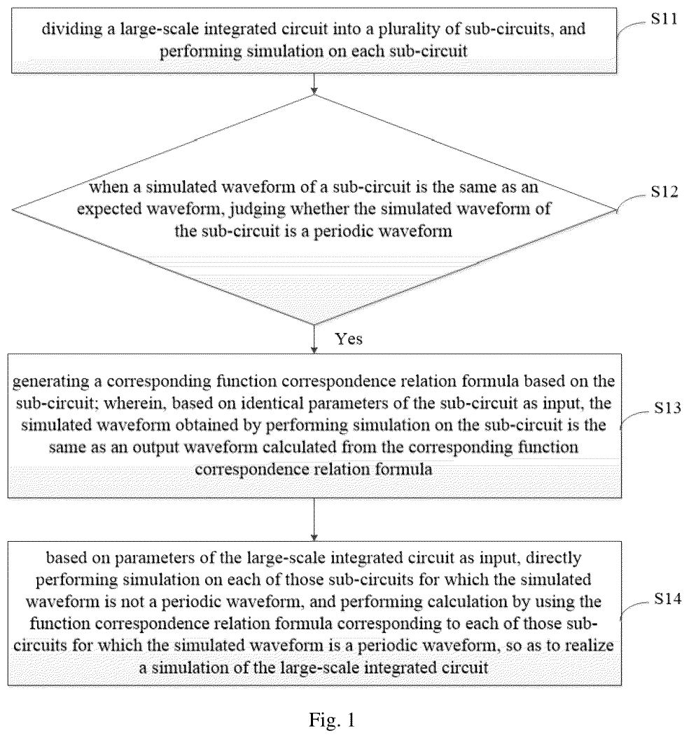

Please refer to FIG. 1, which is a flow chart of a quick simulation method for an integrated circuit provided by an embodiment of the present application, the method comprises:

S11: dividing a large-scale integrated circuit into a plurality of sub-circuits, and performing simulation on each sub-circuit;

Considering the slow speed and heavy workload when directly performing design and simulation on a whole circuit, the present application generally divides a large-scale integrated circuit into a plurality of sub-circuits, then designs each sub-circuit in sequence, and performs simulation and verification on each designed sub-circuit. Wherein, when performing design and simulation on each sub-circuit, the next sub-circuit is not designed until the currently designed sub-circuit meets the design requirements, that is, until a simulated waveform is the same as an expected waveform.

Wherein, the condition for the simulated waveform being the same as the expected waveform in the present application may be that the respective waveform parameters of the simulated waveform are the same as the respective waveform parameters of the expected waveform.

Moreover, after completing the design of a sub-circuit, an operation of confirming the completion of simulation may be performed, specifically, it may be that a button for confirming the completion of simulation is clicked, and at this time, a processor automatically saves the last simulated sub-circuit module.

S12: when a simulated waveform of a sub-circuit is the same as an expected waveform, judging whether the simulated waveform of the sub-circuit is a periodic waveform;

S13: if it is judged that the simulated waveform of the sub-circuit is a periodic waveform, then generating a corresponding function correspondence relation formula based on the sub-circuit; wherein, based on identical parameters of the sub-circuit as input, the simulated waveform obtained by performing simulation on the sub-circuit is the same as an output waveform calculated from the corresponding function correspondence relation formula;

Considering that an amount of calculation of simulation on a sub-circuit with a changing waveform is relatively large for EDA software, and the type of sub-circuit with a periodic waveform is one type of sub-circuit with a changing waveform, and output waveforms of most sub-circuits in the prior art are periodic waveforms, therefore, how to improve the simulation speed for sub-circuits with periodic waveforms is an urgent technical problem to be solved for technicians in this field.

In order to solve the above-mentioned technical problem, after finishing the design of a sub-circuit as it is judged that the simulated waveform of the sub-circuit is the same as the expected waveform, the present application further judges whether the simulated waveform of the sub-circuit is a periodic waveform, and if it is judged that the simulated waveform of the sub-circuit is a periodic waveform, a function correspondence relation formula is generated based on the sub-circuit, wherein, based on identical input parameters, the output waveform calculated based on the function correspondence relation formula is the same as the simulated waveform obtained by EDA simulation that is directly performed on the sub-circuit. At this time, when performing simulation on the sub-circuit with a periodic waveform, the simulation thereof may be replaced by using the function correspondence relation formula to perform simulation calculation on the sub-circuit, thereby improving the simulation speed for the large-scale integrated circuit.

Furthermore, it should be noted that, the function correspondence relation formula is automatically generated in the process of designing the sub-circuit, instead of being generated in the process of simulation, so that when a circuit designer is designing a next sub-circuit, the simulation software can perform calculation and automatically generate the function correspondence relation formula of the last sub-circuit, thus increasing the speed of obtaining a result of final simulation.

Wherein, an approach for judging whether the simulated waveform of the sub-circuit is a periodic waveform may be that the software directly judges the simulated waveform of the sub-circuit, or it may be that an user knows what type of output waveform the sub-circuit would output in advance, and after clicking the button for confirming the completion of simulation in the above-mentioned steps, the user presents the type of output waveform of the sub-circuit as input into the processor, and the processor judges whether the simulated waveform of the sub-circuit is a periodic waveform based on the input from the user.

It should be noted that, the type of periodic waveform in the present application may include, but is not limited to, periodic square waves, periodic triangular waves, periodic sine waves, etc., and may also be other types of periodic waves, which are not particularly limited herein.

S14: based on parameters of the large-scale integrated circuit as input, directly performing simulation on each of those sub-circuits for which the simulated waveform is not a periodic waveform, and performing calculation by using the function correspondence relation formula corresponding to each of those sub-circuits for which the simulated waveform is a periodic waveform, so as to realize a simulation of the large-scale integrated circuit.

On the basis of completion of the above-mentioned steps, when simulation needs to be performed on a large-scale integrated circuit, the direct software simulation on those sub-circuits for which the simulated waveform is not a periodic waveform does not adversely affect the simulation speed of the large-scale integrated circuit, and a way of performing simulation on those sub-circuits for which the simulated waveform is a periodic waveform is changed from software simulation into using the corresponding function correspondence relation formula to do calculation, so there is no need to perform complicated matrix calculations, thereby increasing the simulation speed.

Specifically, when a circuit designer performs simulation on a whole large-scale integrated circuit, in order to obtain an accurate result, the most common way of simulation (that is, the way of simulation in the prior art) may be adopted, but this way of simulation is very time-consuming and often takes several hours or even several days; however, if the circuit designer only wants to verify the correctness of the circuit or have a look at an output trend of the circuit, the way of simulation provided by the present application can be used to perform simulation on it. Specifically, by clicking on a quick simulation button on the simulation software, a circuit simulator replaces all sub-circuits which output periodic waveforms such as square waves, sine waves and triangle waves with the obtained function correspondence relation formula of the respective waveform parameters in relation to the sub-circuit according to input parameters of the large-scale integrated circuit (for example, a sub-circuit outputs a square wave, the circuit simulator inputs the input parameters of this sub-circuit into a function correspondence relation formula of the amplitude parameter of the square wave corresponding to this sub-circuit, a function correspondence relation formula of the cyclic period parameter thereof, and a function correspondence relation formula of a duty cycle parameter thereof, respectively, so as to calculate out an amplitude, a cyclic period, and a duty cycle of the square wave under the current input parameters, thereby quickly obtaining a simulation output result of this sub-circuit), so as to perform simulation to quickly obtain a simulation result, thereby tremendously increasing the simulation speed.

Specifically, assuming that a large-scale integrated circuit in the present application comprises three sub-circuits, and the three sub-circuits are connected in series, i.e., the input of the second sub-circuit is the output of the first sub-circuit and the input of the third sub-circuit is the output of the second sub-circuit, at this time, if simulated waveforms of the second sub-circuit and the third sub-circuit are periodic waveforms, then, when performing simulation on the large-scale integrated circuit, inputting the input parameters of the large-scale integrated circuit into the first sub-circuit, wherein the first sub-circuit runs simulation for the input parameters, and then performing calculation from an output result of the first sub-circuit based on a function correspondence relation formula corresponding to the second sub-circuit, and in the same way, performing calculation from an output result of the second sub-circuit based on a function correspondence relation formula corresponding to the third sub-circuit to finish simulation of the third sub-circuit, and at this time, the corresponding output result of the third sub-circuit is taken as an output result of the large-scale integrated circuit. Since waveforms obtained by performing simulation on sub-circuits and waveforms obtained by calculation based on the corresponding function correspondence relation formulas are the same, a simulated waveform obtained in the manner provided by the present application would be the same as an original simulated waveform, and meanwhile the amount of calculation for an EDA simulation software can be greatly reduced and the simulation speed thereof can be increased.

In conclusion, the simulation method in the present application does not need to perform complicated matrix calculations on the circuit, thereby improving the simulation speed when the integrated circuit is subject to transient analysis.

On the basis of the above-mentioned embodiment:

As an optional embodiment, the step of generating a corresponding function correspondence relation formula based on the sub-circuit comprises:
acquiring N groups of input parameters of the sub-circuit, wherein N is an integer greater than 2;
performing simulation on the sub-circuit based on each group of input parameters among the N groups of input parameters respectively, to obtain N simulated waveforms;
sampling the N simulated waveforms respectively, to obtain N waveform parameters;
obtaining the function correspondence relation formula based on the N groups of input parameters and the N waveform parameters.

This embodiment aims to provide a specific implementation way of generating a function correspondence relation formula corresponding to a sub-circuit, in particular, obtaining corresponding N simulated waveforms based on N groups of input parameters of the sub-circuit, and then respectively sampling the N simulated waveforms to obtain corresponding N waveform parameters, and then generating a corresponding function correspondence relation formula based on the N waveform parameters and the N groups of input parameters.

Wherein, the number of input parameters in the present application may be designed to be positively correlated with the number of nodes and branches of the sub-circuit, for example, when the sub-circuit has a nodes and b branches, the number of input parameters N may be designed to be A times of a*b, wherein, the larger the value of A, the higher the corresponding simulation accuracy.

Besides, each group of input parameters may correspondingly comprise a plurality of types of input parameters simultaneously input into the sub-circuit, such as comprising voltage, current, frequency, etc., which are not particularly limited herein.

It should be noted that, as an optional embodiment, when the simulated waveform of the sub-circuit is a square wave, the corresponding waveform parameters may comprise, but are not limited to, an amplitude, a cyclic period and a duty cycle of the current square wave, at this time, the number of the waveform parameters obtained by sampling may be 3N, and correspondingly the 3N waveform parameters obtained are N amplitude parameters, N cyclic period parameters, and N duty cycle parameters, respectively. When the simulated waveform of the sub-circuit is a sine wave, the corresponding waveform parameters are an amplitude, a cyclic period and an initial phase angle of the current sine wave, and at this time, the number of waveform parameters obtained by sampling may also be 3N, and correspondingly the 3N waveform parameters obtained are N amplitude parameters, N cyclic period parameters, and N initial phase angle parameters, respectively. When the simulated waveform of the sub-circuit is a triangular wave, the corresponding waveform parameters are an amplitude, a cyclic period and a duty cycle of the current triangular wave, and at this time, the number of waveform parameters obtained by sampling may also be 3N, and correspondingly the 3N waveform parameters obtained are N amplitude parameters, N cyclic period parameters, and N duty cycle parameters, respectively.

It should also be noted that, in this embodiment, ordinary square waves and periodic pulses both belong to the aforementioned square wave herein, ordinary sine waves and half-sine waves in a steamed bread shape both belong to the aforementioned sine wave herein, and ordinary triangular waves and sawtooth waves both belong to the aforementioned triangular wave herein.

Taking a square wave as an example, after obtaining N amplitude parameters, N cyclic period parameters and N duty cycle parameters, the N amplitude parameters are stored in one-to-one correspondence with the N input parameters, the N cyclic period parameters are stored in one-to-one correspondence with the N input parameters, and the N duty cycle parameters are stored in one-to-one correspondence with the N input parameters. Then generating a corresponding amplitude function correspondence relation formula/cyclic period function correspondence relation formula/duty cycle function correspondence relation formula based on the N amplitude parameters/the N cyclic period parameters/the N duty cycle parameters in relation with the N input parameters.

In conclusion, the approach of this embodiment can realize the generation of corresponding function correspondence relation formulas, and the way of realization thereof is simple and reliable.

As an optional embodiment, the step of obtaining the function correspondence relation formula based on the N groups of input parameters and the N waveform parameters comprises:

taking the input parameters as independent variables and the waveform parameters as dependent variables, carrying out linear regression calculation to obtain a linear regression expression formula corresponding to the sub-circuit, and taking the obtained linear regression expression formula as the function correspondence relation formula.

This embodiment aims to provide a specific implementation way of obtaining the function correspondence relation formula based on the N groups of input parameters and the N waveform parameters.

Specifically, taking the input parameters as independent variables and the waveform parameters as dependent variables, carrying out linear regression calculation to obtain a linear regression expression formula corresponding to the sub-circuit, and taking the obtained linear regression expression formula as the function correspondence relation formula.

Specifically, a square wave is taken as an example again, the waveform parameters corresponding to the square wave comprise an amplitude parameter, a cyclic period parameter and a duty cycle parameter;
1) assuming that the number of input parameters inputted into the sub-circuit at the same time is Z, the number of independent variables is determined to be Z, and at this time, the amplitude parameter, that is, a dependent variable Y, can be expressed as:

Y=A₀+A₁X₁+A₂X₂+ . . . +A_{z}X_{z}+e;
wherein, e is an error value, and A₀, A₁, A₂, . . . , and A_{z} are to-be-estimated regression coefficients.
2) assuming that N (N=A*a*b) groups of observed values (xᵢ₁, xᵢ₂, . . . , x_{iz}, yᵢ), i=1, 2, . . . , N, of the dependent variable Y and the independent variables A₀, A₁, A₂, . . . , and A_{z} meet that: yᵢ=A₀+A₁xᵢ₁+A₂xᵢ₂+ . . . +A_{z}X_{iz}+eᵢ, meanwhile, assuming that e, satisfies the Gauss-Markov hypothesis, that is, an expected value of the error value is zero, a covariance of the error value is zero, variances of the error value are equal for different independent variables, and the error value has a Normal Distribution;
3) in order to eliminate the differences of units and value ranges to make it convenient to perform statistical analysis on estimated values of the regression coefficients, the original data of the independent variables X is normalized;
4) searching for a group of least square estimated values of the regression coefficients to minimize a sum of squares of residual errors of a regression model;
5) calculating the variances and standard deviations of the least square estimated values of the regression coefficients;
6) calculating an estimated value of each of the regression coefficients, the variance and standard deviation of each of the regression coefficients, and a confidence interval of each of the regression coefficients, thereby obtaining an initial linear regression model;
7) performing a significance test of regression coefficients, a significance test of regression equation linear relation and a stability test of model structure on the initial linear regression model, and obtaining a final linear regression model, that is, a linear regression expression formula.

It can be seen that, the linear regression expression formula obtained by means of regression calculation can be used as a function correspondence relation formula of the sub-circuit, and the way of calculation thereof is simple and reliable.

As an optional embodiment, after the step of taking the input parameters as independent variables and the waveform parameters as dependent variables, carrying out linear regression calculation to obtain a linear regression expression formula corresponding to the sub-circuit, the method further comprises:
judging whether the linear regression expression formula has over-fitting or under-fitting;
if the linear regression expression formula has over-fitting or under-fitting, then taking the input parameters as independent variables and the waveform parameters as dependent variables, carrying out nonlinear regression calculation to obtain a nonlinear regression expression formula corresponding to the sub-circuit, and taking the obtained nonlinear regression expression formula as the function correspondence relation formula;
wherein the step of performing calculation by using the function correspondence relation formula corresponding to each of those sub-circuits for which the simulated waveform is a periodic waveform comprises:
performing calculation by using the linear regression expression formula or the nonlinear regression expression formula corresponding to each of those sub-circuits for which the simulated waveform is a periodic waveform.

In order to prevent the linear regression expression formula from over-fitting or under-fitting that would result in inaccurate simulation results, the regression model needs to undergo a secondary test to judge whether the linear regression expression formula corresponding to the sub-circuit has over-fitting or under-fitting.

The waveform parameter being an amplitude parameter of a square wave is taken as an example, a specific way of judging whether there is over-fitting or under-fitting is: selecting K groups of input parameters (wherein the K groups of input parameters are K groups of input parameters that have not been used for acquiring the initial value points, that is, parameter values of the K groups of input parameters are all not equal to any parameter value from the N and M groups of input parameters), and inputting the K groups of input parameters into the final linear regression expression formula and into the circuit simulator respectively, and obtaining two output results by calculation and simulation respectively, and obtaining a difference between the two output results, if the difference value is within a threshold value range for more than K/2 times, it is judged that the linear regression expression formula meets the requirement, and there is no over-fitting or under-fitting, so the linear regression expression formula can be used as a function correspondence relation formula of the amplitude parameter and stored in the circuit simulator (a part of the EDA software). If the difference value is outside the threshold value range for no less than K/2 times, then it is judged that the linear regression expression formula has over-fitting or under-fitting and does not meet the requirement.

When the linear regression expression formula has over-fitting or under-fitting, the step of taking the input parameters as independent variables and the waveform parameters as dependent variables and carrying out nonlinear regression calculation to obtain a nonlinear regression expression formula corresponding to the sub-circuit specifically comprises the following procedures:
1) converting a dependent variable and an independent variable to make the converted two variables have a straight line linear relation, then fitting a straight line linear equation between the converted independent variable and the converted dependent variable by using the least square method, and then restoring the variables in the obtained straight line linear equation to obtain a corresponding curve equation, that is, obtaining an initial value of a regression coefficient in the model;
if the curve cannot be linearized directly, then selecting one or two regression coefficients with a small variation range at first, and setting a cyclic variable which varies within a small possible value range according to a certain step size, these regression coefficients have specific values in each cycle, and after performing conversion of variables on the curve model, a straight line linear regression analysis is performed, and then the variables in the obtained straight line linear equation are restored to obtain a corresponding curve equation, that is, obtaining the initial values of the regression coefficients in the model;
2) searching for a set of values in the respective regression coefficient value-acquiring ranges to minimize a sum of squares of residual errors of the model fitted with actual data, so as to obtain the estimated values of the regression coefficients, thereby acquiring a corresponding nonlinear regression model, that is, a nonlinear regression expression formula;
3) storing the nonlinear regression expression formula in the circuit simulator as a function correspondence relation formula of the amplitude parameter, in correspondence with the sub-circuit. It can be seen that, when the linear regression expression formula has over-fitting or under-fitting, this embodiment can calculate a corresponding nonlinear regression expression formula, thereby improving reliability when performing simulation on a large-scale integrated circuit.

After that, taking input values of the input parameters corresponding to the cyclic period parameter and corresponding to the duty cycle parameter as independent variables respectively, and taking the cyclic period parameter and the duty cycle parameter as dependent variables respectively, performing linear/nonlinear regression calculation, and obtaining a function correspondence relation formula of the cyclic period parameter and a function correspondence relation formula of the duty cycle parameter by fitting respectively, and storing them in the circuit simulator respectively, in correspondence with the sub-circuit.

As an optional embodiment, the step of acquiring N groups of input parameters of the sub-circuit comprises:
acquiring an upper limit value and a lower limit value of input parameters of the sub-circuit;
acquiring N−2 values between the upper limit value and the lower limit value to obtain N−2 groups of input parameters;
taking the N−2 groups of input parameters, the upper limit value, and the lower limit value together as acquired N groups of input parameters.

The present embodiment aims to provide a specific implementation way of obtaining N groups of input parameters of the sub-circuit, specifically, according to an upper limit value and a lower limit value of input parameters of the sub-circuit, values are acquired between the upper limit value and the lower limit value, and the acquired values of input parameters, together with the upper limit value and the lower limit value, are taken as the N groups of input parameters.

It should be noted that, the upper limit value and the lower limit value in the present embodiment may correspond to a safe input range of the sub-circuit, etc., so as to guarantee safety and reliability of operation of the sub-circuit.

It can be seen that, the present embodiment can acquire the N groups of input parameters by means of acquiring values between an upper limit value and a lower limit value. Wherein, when acquiring values between the upper limit value and the lower limit value, the acquired values may be evenly distributed, so that the obtained waveform would be of greater reference value.

As an optional embodiment, after the step of sampling the N simulated waveforms respectively, to obtain N groups of waveform parameters, the method further comprises:
calculating an i^{th} rate of change, which equals (an (i+1)^{th} waveform parameter minus an i^{th} waveform parameter)/(an (i+1)^{th} input parameter minus an i^{th} input parameter), wherein i is an integer that is less than N and not less than 1;
judging whether a difference between an (i+1)^{th} rate of change and the i^{th} rate of change is greater than a difference threshold value;
if the difference between the (i+1)^{th} rate of change and the i^{th} rate of change is greater than the difference threshold value, then recording an i^{th} interval of input parameters corresponding to the i^{th} rate of change and an (i+1)^{th} interval of input parameters corresponding to the (i+1)^{th} rate of change accordingly;
further acquiring values from the i^{th} interval of input parameters and from the (i+1)^{th} interval of input parameters to obtain M groups of input parameters;
the step of performing simulation on the sub-circuit based on each group of input parameters among the N groups of input parameters respectively, to obtain N simulated waveforms, comprises:
performing simulation on the sub-circuit based on each group of input parameters among the M+N groups of input parameters respectively, to obtain M+N simulated waveforms;
wherein the step of sampling the N simulated waveforms respectively, to obtain N waveform parameters, comprises:
sampling the M+N simulated waveforms respectively, to obtain M+N waveform parameters;
the step of obtaining the function correspondence relation formula based on the N groups of input parameters and the N waveform parameters, comprises:
obtaining the function correspondence relation formula based on the M+N groups of input parameters and the M+N waveform parameters.

Considering that when N groups of input parameters are obtained by means of a first time of value-acquiring to obtain N waveform parameters, there may be significant changes between two values of waveform parameters corresponding to two values of input parameters, at this time, it is unknown how the corresponding values of waveform parameters change between the corresponding two values of input parameters, therefore, in order to improve the accuracy of the obtained waveform parameters, in this embodiment, in addition to the N groups of input parameters, a second time of value-acquiring is performed to additionally obtain M groups of input parameters, that is, there are M+N groups of input parameters acquired in total.

A specific way of the second time of value-acquiring is as follows: calculating a rate of (an (i+1)^{th} waveform parameter minus an i^{th} waveform parameter)/(an (i+1)^{th} input parameter minus an i^{th} input parameter) as an i^{th} rate of change, and comparing and judging whether a difference between an (i+1)^{th} rate of change and the i^{th} rate of change is greater than a difference threshold value, and if the difference between the (i+1)^{th} rate of change and the i^{th} rate of change is greater than the difference threshold value, it means that the change of the waveform parameters in this range corresponding to the two adjacent input parameters is nonlinear, that is, a change trend of the waveform parameters in this range corresponding to the two input parameters is unknown, at this time, an i^{th} interval of input parameters and an (i+1)^{th} interval of input parameters corresponding thereto are recorded and additional values are further acquired therefrom.

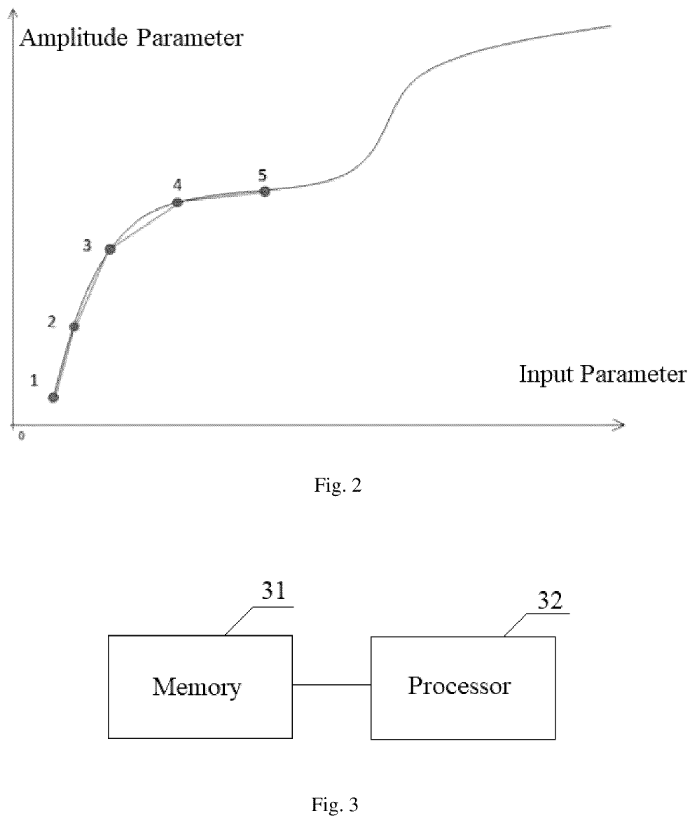

A square wave, for which the waveform parameters comprise an amplitude parameter, a cyclic period parameter and a duty cycle parameter, is taken as an example. Please refer to FIG. 2, which is a schematic diagram of a correspondence relation between an input parameter and an amplitude parameter as provided by an embodiment of the present application.

As an optional embodiment, the step of calculating the i^{th} rate of change comprises:
constructing a coordinate system with the input parameters corresponding to a horizontal axis and the waveform parameters corresponding to a vertical axis;
in the coordinate system, marking out N coordinate points that have a one-to-one correspondence to the N groups of input parameters and the N waveform parameters;
connecting every two neighboring points of the N coordinate points sequentially with line segments;
calculating a slope of a line segment connecting an (i+1)^{th} coordinate point and an i^{th} coordinate point as the i^{th} rate of change.

Specifically, as shown in FIG. 2, the horizontal axis represents each input parameter, the vertical axis represents a corresponding amplitude parameter, points 1-5 are corresponding first five coordinate points, and four line segments are formed between every two neighboring points of the five coordinate points (for convenience of description, Line segment 21 represents the line segment formed between Point 1 and Point 2), calculating an included angle 21 between Line segment 21 and the horizontal X axis to obtain a first slope, calculating an included angle 32 between Line segment 32 and the horizontal X axis to obtain a second slope, and calculating a difference between the first slope and the second slope, or directly calculating a difference between the included angle 32 and the included angle 21, it can be seen that, the difference between the two is very small, which indicates that the change of amplitude parameter is straight-lined and regular; calculating an included angle 43 between Line segment 43 and the horizontal X axis, which corresponds to a third slope, and calculating a difference between the second slope and the third slope, or directly calculating a difference between the included angle 43 and the included angle 32, the difference between the two is greater than the threshold value, which indicates that the change of amplitude parameter is nonlinear and irregular, and thus recording the two intervals of amplitude parameters corresponding to Line segment 32 and Line segment 43; calculating an included angle 54 between Line segment 54 and the horizontal X axis, which corresponds to a fourth slope, and calculating a difference between the fourth slope and the third slope, or directly calculating a difference between the included angle 54 and the included angle 43, the difference between the two is greater than the threshold value, which indicates that the change of amplitude parameter is nonlinear and irregular, and thus recording the two intervals of amplitude parameters corresponding to Line segment 43 and Line segment 54; and after all differences are calculated, saving all the recorded intervals of amplitude parameters 32, 43, and 54 (the interval of amplitude parameters 43 that has been recorded repeatedly is only saved once), and obtaining each interval of input parameters according to the saved intervals of amplitude parameters; thereafter, a second time of value-acquiring is performed on the obtained intervals of input parameters.

Wherein, as an optional embodiment, when further acquiring values from the i^{th} interval of input parameters and from the (i+1)^{th} interval of input parameters, an amount of further acquired values is positively correlated with the difference between the (i+1)^{th} rate of change and the i^{th} rate of change.

Specifically, when further acquiring values, a principle of the difference being positively correlated with the amount of further acquired values may be followed. That is, the larger the difference, the more the amount of further acquired values, and that is, the input parameters in the interval of input parameters are more finely divided. Specifically, in FIG. 2, fewer values may be acquired from the interval 21 and more values may be acquired from the intervals 32, 43, and 54.

Furthermore, the difference threshold value in the present application may be adjusted, and sampling accuracy and calculation speed can be controlled by controlling the magnitude of the difference threshold value, and if an amount of calculation is found to be large, the difference threshold value can be appropriately increased; that is, the smaller the difference threshold value, the greater the accuracy and the corresponding amount of calculation; a specific magnitude of the difference threshold value is determined according to an actual situation, and is not specifically limited herein.

The second time of value-acquiring is performed in the same way for cyclic period parameters and duty cycle parameters respectively, and input values of the respective input parameters corresponding to the cyclic period parameters and the duty cycle parameters are obtained.

At this time, the M groups of input parameters obtained by further acquiring values from all those intervals of input parameters corresponding to differences greater than the difference threshold value, together with the N groups of input parameters obtained at the first time of value-acquiring, are taken as corresponding input parameters, and then M+N simulated waveforms are obtained based on the M+N groups of input parameters obtained by two times of value-acquiring, and M+M waveform parameters are obtained by sampling, and a function correspondence relation formula is generated based on the M+N groups of input parameters and the M+N waveform parameters.

In conclusion, by means of performing the second time of value-acquiring for the input parameters in the present embodiment, accuracy of the generated function correspondence relation formula can be increased, so as to make a result of calculation simulation for a large-scale integrated circuit closer to a result of direct simulation.

Please refer to FIG. 3, which is a structural block diagram of a quick simulation apparatus for an integrated circuit provided by the present application, the apparatus comprises:
a memory 31, configured to store a computer program;
a processor 32, configured to perform steps of the above-mentioned quick simulation method for an integrated circuit when the computer program is executed by the processor.

In order to solve above-mentioned technical problem, the present application further provides a quick simulation apparatus for an integrated circuit, the description thereof can refer to above-mentioned embodiments, which is not repeated herein.

An embodiment of the present application further provides a non-transitory computer storage medium having computer-executable instructions stored thereon, and the computer-executable instructions, when executed by an electronic device, cause the electronic device to perform the above-mentioned quick simulation method for an integrated circuit.

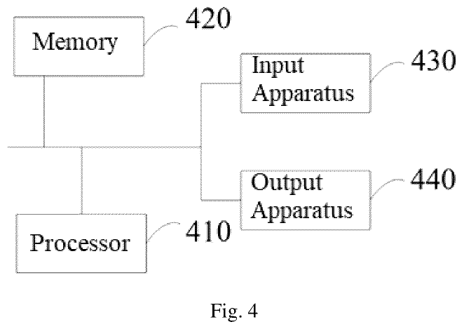

FIG. 4 is a schematic diagram of a hardware structure of an electronic device for executing a quick simulation method for an integrated circuit provided by an embodiment of the present application, as shown in FIG. 4, the device comprises one or more processors 410 and a memory 420, wherein one processor 410 is taken as an example in FIG. 4; the device for executing the quick simulation method for an integrated circuit may also comprise an input apparatus 430 and an output apparatus 440.

The processor 410, the memory 420, the input apparatus 430, and the output apparatus 440 may be interconnected via a bus or other connection approaches, and bus connection is taken as an example in FIG. 4.

As a non-transitory computer readable storage medium, the memory 420 can be used to store a non-transitory software program, a non-transitory computer executable program, and modules thereof, such as program instructions/modules corresponding to the quick simulation method for an integrated circuit of an embodiment herein. The processor 410 executes various functional applications and data processing of a server by executing the non-transitory software program, the instructions and the modules stored in the memory 420, i.e., for performing the quick simulation method for an integrated circuit of the above-mentioned method embodiments.

The memory 420 may comprise a program storage area and a data storage area, wherein, the program storage area may store an operation system, an application program required for at least one function; the data storage area may store data or the like, which is created according to the use of the quick simulation apparatus for an integrated circuit. Additionally, the memory 420 may comprise a high-speed random access memory, and may also comprise a non-transitory memory such as at least one of a disk memory device, a flash memory device, or other kinds of non-transitory solid-state memory device. In some embodiments, the memory 420 optionally may comprise a memory disposed remote from the processor 410, such remote memory may be connected to the quick simulation apparatus for an integrated circuit via a network. Instances of the above-mentioned network comprises, but are not limited to, the Internet, an intranet, a local area network, a mobile communication network, and a combination thereof.

The input apparatus 430 may receive inputted numeric or character information and generate a key signal input related to user settings and functional control of the quick simulation apparatus for an integrated circuit. The output apparatus 440 may comprise a display device such as a display screen.

The one or more modules are stored in the memory 420, and when executed by the one or more processors 410, the one or more modules are caused to perform the quick simulation method for an integrated circuit of any one of the above-mentioned method embodiments.

The above-mentioned product can execute the method provided by the embodiments of the present application, and has functional modules and beneficial effects corresponding to the execution of the method. For technical details which are not described in detail in this embodiment, the methods provided in the embodiments of the present application can be referred to.

The electronic device of embodiments of the present application exists in various forms, comprising but not limited to:
(1) mobile communication devices: these devices are characterized by having a mobile communication function, and its main goal is to provide voice and data communication. Such terminals include smart phones (such as iPhone), multimedia phones, functional phones, and low-end phones;
(2) ultra-mobile personal computer devices: these devices belong to the category of personal computers, and have computing and processing functions, and generally also have mobile internet access characteristics. Such terminals include PDA, MID and UMPC devices, such as iPad;
(3) portable entertainment devices: these devices can display and play multimedia contents. Such devices include: audio and video players (such as iPod), handheld game consoles, e-books, smart toys and portable onboard navigation devices;
(4) servers: equipments that provide computing services, a structure of a server comprises a processor, a hard disk, a memory, a system bus, etc., an architecture of a server is similar to that of a general computer, but due to the need for providing highly reliable services, the requirements thereof is relatively high in aspects such as processing capacity, stability, reliability, security, scalability and manageability;
(5) other electronic devices with data interaction functions;
The apparatus embodiments described above are merely schematic, wherein units illustrated as separate components may or may not be physically separate, and a component displayed as a unit may or may not be a physical unit, i.e., it may be located in one place, or may be distributed on a plurality of network units. Part or all of modules thereof may be chosen according to actual requirements to achieve the purpose of a technical solution of an embodiment.

By the above description of the embodiments, a person skilled in the art can clearly understand that each embodiment may be implemented by means of software in combination with a general-purpose hardware platform, and surely may also be implemented by means of hardware only. Based on such understanding, the above-mentioned technical solution or a part thereof that makes contribution to the prior art may be embodied in the form of a software product, and such a software product may be stored in a computer readable storage medium, such as a ROM/RAM, a magnetic disk, an optical disc, etc., such a software product may comprise instructions for causing a computer device (which may be a personal computer, a server, or a network device, etc.) to perform the method described in the respective embodiments or some part thereof.

It should be noted that, in this Specification, relational terms such as first and second or the like are used only to distinguish an entity or operation from another entity or operation without necessarily requiring or implying that any actual relation or sequence exists between these entities or operations. Moreover, terms of “include”, “comprise”, or any other variation thereof are intended to encompass non-exclusive inclusion, so that a process, a method, an item or an equipment described as comprising a set of elements not only comprises these elements, but also comprises other elements that are not explicitly listed or are inherent to such a process, a method, an item, or an equipment. In absence of a further limitation, an element defined by a phrase “comprise a/an . . . ” does not preclude the existence of another identical element in the process, the method, the item, or the equipment in which this element is comprised.

A person skilled in the art may further be aware that units and algorithmic steps of each example described in connection with the embodiments disclosed herein can be realized in electronic hardware, computer software, or a combination of the two, and for clearly explaining the interchangeability of hardware and software, the above-mentioned explanation has described the components and steps of the respective examples according to functions thereof in a general manner. Whether these functions are performed in hardware or software depends on specific application and design constraints of the technical solution. A person skilled in the art may use different methods for each particular application to implement the described functions, but such implementation should not be considered to exceed the scope of the present application.

The above description of the disclosed embodiments enables a person skilled in the art to implement or use the present invention. Various modifications to these embodiments are evident to a person skilled in the art, and general principles defined herein may be implemented in other embodiments without departing from the spirit or scope of the present invention. Thus, the present application is not limited to the embodiments illustrated herein, but is intended to conform to the broadest scope consistent with the principles and novel features disclosed herein.

What is claimed is:

1. A quick simulation method for an integrated circuit, comprising:
dividing a large-scale integrated circuit into a plurality of sub-circuits, and performing simulation on each sub-circuit;
when a simulated waveform of a sub-circuit is the same as an expected waveform, judging whether the simulated waveform of the sub-circuit is a periodic waveform;
if it is judged that the simulated waveform of the sub-circuit is a periodic waveform, then generating a corresponding function correspondence relation formula based on the sub-circuit; wherein, based on identical parameters of the sub-circuit as input, the simulated waveform obtained by performing simulation on the sub-circuit is the same as an output waveform calculated from the corresponding function correspondence relation formula;
based on parameters of the large-scale integrated circuit as input, directly performing simulation on each of those sub-circuits for which the simulated waveform is not a periodic waveform, and performing calculation by using the function correspondence relation formula corresponding to each of those sub-circuits for which the simulated waveform is a periodic waveform, so as to realize a simulation of the large-scale integrated circuit.

2. The quick simulation method for an integrated circuit according to claim 1, wherein, the step of generating a corresponding function correspondence relation formula based on the sub-circuit comprises:
acquiring N groups of input parameters of the sub-circuit, wherein N is an integer greater than 2;
performing simulation on the sub-circuit based on each group of input parameters among the N groups of input parameters respectively, to obtain N simulated waveforms;
sampling the N simulated waveforms respectively, to obtain N waveform parameters;
obtaining the function correspondence relation formula based on the N groups of input parameters and the N waveform parameters.

3. The quick simulation method for an integrated circuit according to claim 2, wherein, the step of obtaining the function correspondence relation formula based on the N groups of input parameters and the N waveform parameters comprises:
taking the input parameters as independent variables and the waveform parameters as dependent variables, carrying out linear regression calculation to obtain a linear regression expression formula corresponding to the sub-circuit, and taking the obtained linear regression expression formula as the function correspondence relation formula.

4. The quick simulation method for an integrated circuit according to claim 3, wherein, after the step of taking the input parameters as independent variables and the waveform parameters as dependent variables, carrying out linear regression calculation to obtain a linear regression expression formula corresponding to the sub-circuit, the method further comprises:
judging whether the linear regression expression formula has over-fitting or under-fitting;
if the linear regression expression formula has over-fitting or under-fitting, then taking the input parameters as independent variables and the waveform parameters as dependent variables, carrying out nonlinear regression calculation to obtain a nonlinear regression expression formula corresponding to the sub-circuit, and taking the obtained nonlinear regression expression formula as the function correspondence relation formula;
wherein the step of performing calculation by using the function correspondence relation formula corresponding to each of those sub-circuits for which the simulated waveform is a periodic waveform comprises:
performing calculation by using the linear regression expression formula or the nonlinear regression expression formula corresponding to each of those sub-circuits for which the simulated waveform is a periodic waveform.

5. The quick simulation method for an integrated circuit according to claim 2, wherein, the step of acquiring N groups of input parameters of the sub-circuit comprises:
acquiring an upper limit value and a lower limit value of input parameters of the sub-circuit;
acquiring N−2 values between the upper limit value and the lower limit value to obtain N−2 groups of input parameters;
taking the N−2 groups of input parameters, the upper limit value, and the lower limit value together as acquired N groups of input parameters.

6. The quick simulation method for an integrated circuit according to claim 2, wherein, after the step of sampling the N simulated waveforms respectively, to obtain N waveform parameters, the method further comprises:
calculating an i^{th} rate of change, which equals (an (i+1)^{th} waveform parameter minus an i^{th} waveform parameter)/(an (i+1)^{th} input parameter minus an i^{th} input parameter), wherein i is an integer that is less than N and not less than 1;
judging whether a difference between an (i+1)^{th} rate of change and the i^{th} rate of change is greater than a difference threshold value;
if the difference between the (i+1)^{th} rate of change and the i^{th} rate of change is greater than the difference threshold value, then recording an i^{th} interval of input parameters corresponding to the i^{th} rate of change and an (i+1)^{th} interval of input parameters corresponding to the (i+1)^{th} rate of change accordingly;
further acquiring values from the i^{th} interval of input parameters and from the (i+1)^{th} interval of input parameters to obtain M groups of input parameters;
wherein the step of performing simulation on the sub-circuit based on each group of input parameters among the N groups of input parameters respectively, to obtain N simulated waveforms, comprises:
performing simulation on the sub-circuit based on each group of input parameters among the M+N groups of input parameters respectively, to obtain M+N simulated waveforms;
wherein the step of sampling the N simulated waveforms respectively, to obtain N waveform parameters, comprises:
sampling the M+N simulated waveforms respectively, to obtain M+N waveform parameters;
wherein the step of obtaining the function correspondence relation formula based on the N groups of input parameters and the N waveform parameters comprises:
obtaining the function correspondence relation formula based on the M+N groups of input parameters and the M+N waveform parameters.

7. The quick simulation method for an integrated circuit according to claim 6, wherein, when further acquiring values from the i^{th} interval of input parameters and from the (i+1)^{th} interval of input parameters, an amount of further acquired values is positively correlated with the difference between the (i+1)^{th} rate of change and the i^{th} rate of change.

8. The quick simulation method for an integrated circuit according to claim 6, wherein, the step of calculating the i^{th} rate of change comprises:
constructing a coordinate system with the input parameters corresponding to a horizontal axis and the waveform parameters corresponding to a vertical axis;
in the coordinate system, marking out N coordinate points that have a one-to-one correspondence to the N groups of input parameters and the N waveform parameters;
connecting every two neighboring points of the N coordinate points sequentially with line segments;
calculating a slope of a line segment connecting an (i+1)^{th} coordinate point and an i^{th} coordinate point as the i^{th} rate of change.

9. The quick simulation method for an integrated circuit according to claim 2, wherein, when the simulated waveform is a periodic square wave or a periodic triangular wave, the waveform parameters comprise an amplitude, a cyclic period and a duty cycle of the square wave or the triangular wave; when the simulated waveform is a sine wave, the waveform parameters comprise an amplitude, a cyclic period and an initial phase angle of the sine wave.

10. A quick simulation apparatus for an integrated circuit, comprising:
a memory, configured to store a computer program;
a processor, configured to perform the quick simulation method for an integrated circuit according to any one of claims 1-9 when the computer program is executed by the processor.

11. A non-transitory computer storage medium, comprising: the non-transitory computer storage medium has computer-executable instructions stored thereon, and the computer-executable instructions, when executed by an electronic device, cause the electronic device to perform the quick simulation method for an integrated circuit according to claim 1.
